(19) United States
(12) Patent Application Publication
(10) Pub. No.: US 2025/0331139 A1
(43) Pub. Date: Oct. 23, 2025

(54) COOLING DEVICE FOR COOLING AN ELECTRICAL AND/OR ELECTRONIC ASSEMBLY

(71) Applicant: Robert Bosch GmbH, Stuttgart (DE)

(72) Inventors: Max Florian Beck, Vaihingen An Der Enz (DE); Maik Paehrisch, Reutlingen (DE)

(21) Appl. No.: 18/870,784

(22) PCT Filed: May 24, 2023
(86) PCT No.: PCT/EP2023/063872

§ 371 Date: Dec. 2, 2024

(30) Foreign Application Priority Data
Jun. 7, 2022 (DE) 10 2022 205 731.7

(51) Int. Cl. H05K 7/20; F28F 13/12

(52) U.S. Cl. CPC H05K 7/20927; F28F 13/12

(57) ABSTRACT

The invention relates to a cooling device for cooling an electrical and/or electronic assembly (2), said cooling device comprising: a top plate (3) and a bottom plate (4), the bottom plate (4) being a deep-drawn component having a depression (40), the top plate (3) and the bottom plate (4) being arranged such that, due to the depression (40) a cooling channel (5) is formed between the top plate (3) and the bottom plate (4), the top plate (3) and the bottom plate (4) being connected to one another at a contact region (8) outside the depression (40), it being possible for a cooling fluid flow of a cooling fluid to flow through the cooling channel (5) along the longitudinal direction (11), the cooling device (1) also comprising at least one turbulator (6) that is arranged inside a turbulator section (56) of the cooling channel (5). According to the invention, a turbulence portion (61) for generating local turbulence in the flow of the cooling fluid and a blocking region (62) for locally blocking the flow of the cooling fluid are formed on the turbulator (6).

### BACKGROUND

The present invention relates to a cooling device for the cooling of an electrical and/or electronic assembly, as well as an electronic arrangement.

Power modules, such as inverter structures or converter structures, are used in hybrid vehicles or electric vehicles. For example, inverters that provide phase currents to the electric machine are used to operate an electric machine. The power modules can, for example, comprise a support substrate with conductor tracks on which, for example, power semiconductors are arranged which, together with the support substrate, form an electronic unit. During operation, heat is generated by the electrical unit and must be dissipated to a cooling device. For this purpose, the electronic unit is thermally connected to the cooling device. It is known to provide cooling devices with cooling channels, within which a cooling fluid can flow to dissipate the heat from the cooling element. What are referred to as “turbulators” can be provided in the cooling channels and ensure improved heat dissipation from the cooling device to the cooling fluid flowing through the cooling device. The turbulators generate turbulent flows and increase the cooling surface.

### SUMMARY

Proposed according to the invention is a cooling device for cooling an electrical and/or electronic assembly. The cooling device comprises a top plate and a bottom plate, the bottom plate being a deep-drawn component having a depression, the top plate and the bottom plate being arranged such that, due to the depression, a cooling channel is formed between the top plate and the bottom plate, the top plate and the bottom plate being connected to one another at a contact region outside the depression, it being possible for a cooling fluid flow of a cooling fluid to flow through the cooling channel along the longitudinal direction, the cooling device also comprising at least one turbulator that is arranged inside the turbulator section of the cooling channel. A turbulence portion for generating local turbulence in the flow of the cooling fluid and a blocking area for locally blocking the flow of the cooling fluid are formed on the turbulator.

Compared to the prior art, the cooling device having the features of the disclosure has a particularly high degree of efficiency with regard to cooling the electrical and/or electronic assembly to be cooled. The blocking region on the turbulator can block or severely restrict a bypass flow through a bypass region on the edge of the turbulator. The flow of the cooling fluid is thus directed through the cooling element through the turbulence portion of the turbulator. For example, the turbulence portion of the turbulator is arranged below the electrical and/or electronic assembly to be cooled. The turbulence portion of the turbulators is designed such that the cooling fluid flowing through the turbulence portion of the turbulator is swirled in said region. In contrast, the blocking region of the turbulator blocks the flow adjacent to the turbulence portion, so that the cooling fluid cannot flow past the turbulator in said region. Therefore, the cooling fluid can only flow through the turbulence portion of the turbulator when flowing through the cooling channel and not past it.

According to one advantageous embodiment, it is provided that the blocking region projects from an edge of the turbulence portion into a bypass region of the cooling channel between the bottom plate and the top plate. At the edge of the depression, the bottom plate extends towards the top plate in the contact region, so that the cooling channel is tapered in this direction. The blocking region projects into this tapered region, so it is at least partially sealed by the blocking region.

According to one advantageous exemplary embodiment, it is provided that the blocking region of the turbulator extends from the turbulence portion of the turbulent to the contact region between the top plate and the bottom plate. The region between the turbulence portion and the contact region is thus sealed, and the cooling fluid cannot flow past the turbulence portion of the turbulator. The cooling fluid thus only flows through the cooling channel in the turbulence portion of the turbulator. As a result, no flow through the cooling fluid is lost on the edges of the cooling channel. The electrical and/or electronic assembly to be cooled can be in particular effectively cooled.

According to one advantageous exemplary embodiment, it is provided that the turbulator is formed from a curved metal sheet, whereby the metal sheet is bent such that the blocking region is oriented flat against the longitudinal direction. A turbulator of this kind can be produced in a straightforward and inexpensive manner. For example, the same metal sheet or a similar metal sheet can be used for the bottom plate, the top plate, and the turbulator. The turbulence portion and the blocking region of the turbulator can then be shaped in the turbulator, for example by cutting and shaping the metal sheet, for example by punching and bending.

According to one advantageous exemplary embodiment, it is provided that the blocking region of the turbulator extends at least partially flat in a plane perpendicular to the longitudinal direction. The flow at the edge of the cooling channel is thus particularly well blocked. The flow at the edge of the cooling channel thus hits the blocking region perpendicularly, for example, and is thus blocked by the latter.

According to an advantageous exemplary embodiment, it is provided that the blocking region of the turbulator has a shape adapted to a geometry of the bottom plate, in particular at an edge of the depression. The blocking region on the bottom plate can thus be connected to the bottom plate as far as the contact region and, e.g., connected to the bottom plate as far as the contact region. As a result, a flow of the cooling fluid adjacent to the turbulence portion of the turbulator can advantageously be well blocked.

According to one advantageous exemplary embodiment, it is provided that the blocking region extends flat from the turbulence portion to the contact region between the top plate and the bottom plate.

According to one advantageous exemplary embodiment, it is provided that a plurality of, in particular similarly designed, blocking regions are formed on the turbulator. Cooling fluid flowing from the turbulator region in the direction of the contact region can thus be blocked at various locations. For example, if a flow of cooling liquid forms again downstream of a blocking region in the flow direction due to cooling liquid flowing out of the turbulator region, then this can be blocked by the next blocking region of the turbulator.

According to one advantageous embodiment, it is provided that the blocking regions are formed at opposite edges of the turbulence portion. The bypasses can thus be sealed on both sides of the cooling channel in the contact region.

The cooling device can be further comprised of an electronic arrangement, the electronic arrangement further comprising at least one electrical and/or electronic assembly to be cooled, whereby the electronic component is arranged on the top plate or on the bottom plate.

### BRIEF DESCRIPTION OF THE DRAWINGS

Exemplary embodiments of the invention are shown in the drawings and explained in more detail in the subsequent description. Shown are:

FIG. 1 a cross-section through an exemplary embodiment of an electronic arrangement comprising a cooling device,

FIG. 2 a cut-out of the bottom plate and the turbulator of the cooling device of FIG. 1,

FIG. 3 a cut-out of the bottom plate and the turbulator of the cooling device of FIG. 1.

### DETAILED DESCRIPTION

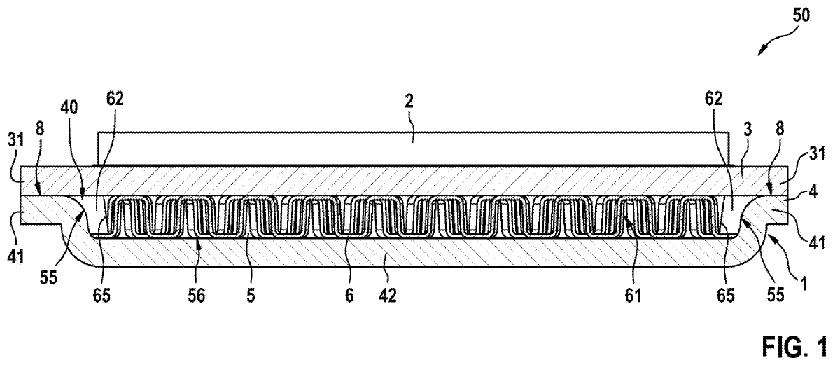

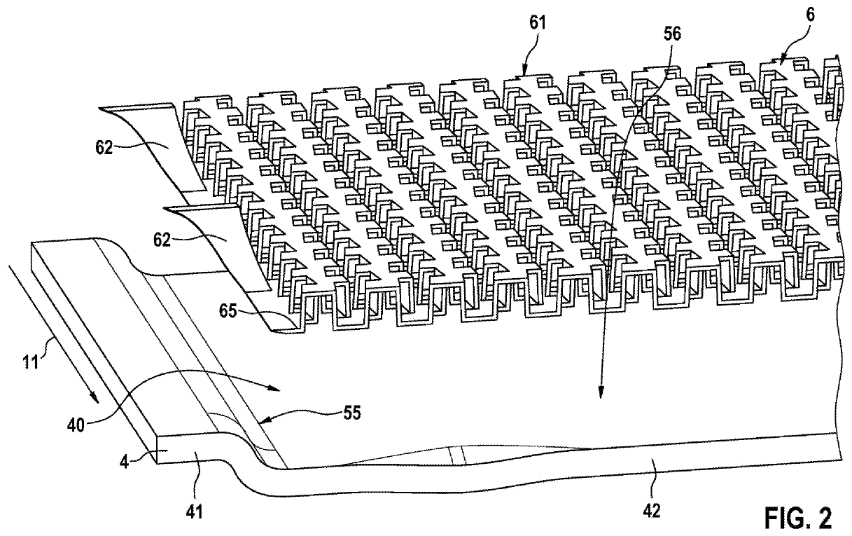

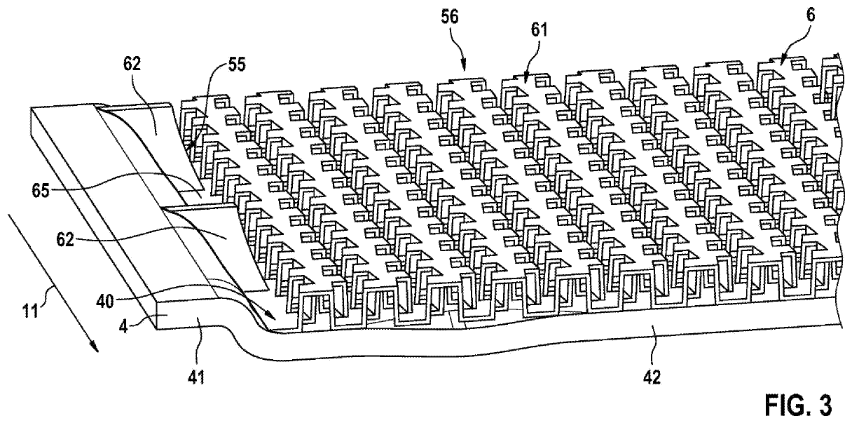

FIG. 1 shows a sectional view through an exemplary embodiment of an electronic arrangement 50. The electronic arrangement 50 comprises a cooling device 1 and an electrical and/or electronic assembly on the cooling device 1. FIG. 2 and FIG. 3 show representations of the bottom plate 4 and the turbulator 6 of the cooling device 1, without the top plate 3 for better clarity.

The cooling device 1 is provided for cooling the electrical and/or electronic assembly 2, for example a power circuit. These may be, for example, power circuits, such as inverter structures or converter structures, of hybrid vehicles or electric vehicles. The electrical and/or electronic assembly 2 can, e.g., be designed as a power module and comprise, for example, a support substrate having traces on which, for example, power semiconductors are arranged to form an electronic unit together with the support substrate. During operation, heat is generated by the electrical and/or electronic assembly 2 and must be dissipated to a cooling device 1. For this purpose, the electrical and/or electronic assembly 2 is arranged on the cooling device 1, for example on a contact surface of a top plate 3 or a bottom plate 4. One or multiple layers can be arranged between the cooling device 1 and the electrical and/or electronic assembly 2 for fastening and thermally connecting the electrical and/or electronic assembly 2 to the cooling element 1. For example, a copper coating can be provided on the contact surface of the top plate 3 facing the electrical and/or electronic assembly 2. As in the exemplary embodiments shown, multiple electrical and/or electronic assemblies 2 can be arranged on the cooling device 1, for example next to each other, on the top plate 3 of the cooling device 1. Each of the electrical and/or electronic assemblies 2 is thus thermally connected to the cooling device 1 and attached thereto.

The bottom plate 4 and the top plate 3 form outer walls of the cooling device 1. The bottom plate 4 forms a bottom side of the cooling device 1. The top plate 3 forms a top side of the cooling device 1. The bottom plate 4 and the top plate 3 can, for example, be made of a material with high level of thermal conductivity, e.g. a metal such as aluminum. The bottom plate 4 and the top plate 3 are formed from metal sheets. The bottom plate 4 and/or the top plate 3 each have, e.g., a constant thickness. The bottom plate 4 and the top plate 3 can, e.g., have the same thickness. However, the bottom plate 4 and the top plate 3 can also have different thicknesses.

A depression 40 is formed in the bottom plate 4. The bottom plate 4 is therefore designed to be essentially trough-shaped. The top plate 3 is arranged on the bottom plate 4 such that the depression 40 in the bottom plate 4 is covered by the top plate 3. The bottom plate 4 and the top plate 3 are arranged together such that, due to the depression 40, a cooling channel 5 is formed between the bottom plate 4 and top plate 3. The cooling channel 5 extends between the bottom plate 4 and the top plate 3. The bottom plate 4 and the top plate 3 form walls delimiting the cooling channel 5. The bottom plate 4 is designed as a deep-drawn part. An edge 41 of the bottom plate 4 which is, e.g., formed in a plane is connected to an edge 31 of the top plate 3. The region where the bottom plate 4 is connected to the top plate 3 is referred to as the contact region 8. The edge 41 of the bottom plate 4 surrounds the depression 40 in the bottom plate 4 in a circumferential manner. The edge 41 of the bottom plate 4 adjoins the edge 31 of the top plate 3, for example, either directly or with the interposition of an intermediate layer. The edge 41 of the bottom plate 4 is firmly connected, in particular soldered, to the edge 31 of the top plate 3. The edge 41 of the bottom plate 4 can be connected, in particular soldered, to the edge 31 of the top plate 3 directly or with the interposition of one or more intermediate layers or intermediate elements. The edge 41 of the bottom plate 4 is connected to the edge 31 of the top plate 3, e.g. by means of a brazing process. The edge 41 of the bottom plate 4 is connected, in particular soldered, to the edge 31 of the top plate 3 in a completely circumferential manner.

In the region of the depression 40, the bottom plate 4 is at a distance from the top plate 3, so that a cavity through which the cooling channel 5 runs is formed between the bottom plate 4 and the top plate 3. As in this exemplary embodiment, the edge 41 of the bottom plate 40 can extend in a flat manner in a first plane. Furthermore, a portion of the sheet metal 42 of the bottom plate 40, which forms, for example, a bottom of the depression 40, can extend in a level manner in a second plane, which is in particular parallel to the first plane. As a result, the edge 41 of the bottom plate 40 and the portion of sheet metal 42 of the bottom plate 4 are each arranged level and parallel to each other. The top plate 3 can, e.g., be designed to be level, or also as a deep-drawn part. The depression 40, and thus the cooling channel 5, can be elongated with respect to a bottom plate 4, at least portions thereof having a rectangular shape. At least sections of the cooling channel 5 extend along a longitudinal direction 11. Preferably, when viewed on a sheet metal plane of the top plate 3, the cooling channel 5 comprises an elongated region, in particular with rectangular geometry, which extends along the longitudinal direction 11, particularly defined by a straight line.

An intermediate plate can, for example, be arranged between the top plate 3 and bottom plate 4. For example, such an intermediate plate can provide an additional distance to an upper side of the top plate 4 in order to adjust a height of the cooling channel 5. Alternatively, as in the exemplary embodiment shown in the drawings, the top plate 3 and the first portion of sheet metal 41 of the bottom plate 4 can also directly adjoin one another.

The cooling device 1 further comprises an inlet opening (not shown in the drawings), via which a cooling fluid can be supplied to the cooling channel 5 in the cooling device 1. The cooling device 1 further comprises an outlet opening, through which the cooling fluid can flow out of the cooling channel 5 and the cooling device 1. The cooling fluid can be water, for example. The inlet opening and/or the outlet opening can, for example, be formed by openings in the depression 40 of the bottom plate 4. The openings can, e.g., be apertures in the bottom plate 4. For example, a feed nozzle can also be arranged or formed at the inlet opening. In the same way, an outlet nozzle can be arranged or formed at the outlet opening. A cooling fluid flow of a cooling fluid can flow through the cooling channel 5 from the inlet opening to the outlet opening. A cooling fluid can flow into the cooling channel 5 through the inlet opening of the cooling device 1 and flow out of the cooling channel 5 of the cooling device 1 through the outlet opening of the cooling device 1. The cooling channel 5 is designed to feed cooling fluid through the cooling device 1. The cooling channel 5 in the cooling device 1 extends in the cooling device 1 from the inlet opening to the outlet opening. A cooling fluid flow of a cooling fluid can flow through the cooling channel 5 in the longitudinal direction 11 from the inlet opening to the outlet opening.

The cooling device 1 further comprises at least one turbulator 6. The turbulator 6 is arranged within the cooling channel 5. The turbulator 6 is arranged in a turbulator section 56 of the cooling channel 5 extending along the longitudinal direction 11. The turbulator 6 is arranged between the top plate 3 and the bottom plate 4. The turbulator 6 can extend from the top plate 3 to the bottom plate 4, completely through the cooling channel 5. In particular, the turbulator 6 is in direct and/or indirect heat-conductive contact with the top plate 3 and the bottom plate 4. The turbulator 6 is, e.g., attached to the top plate 3 and/or the bottom plate 4 using a brazing process. Cooling fluid flows through the turbulator 6 in the longitudinal direction 11 parallel to, for example, the level top plate 3 and/or the portion of sheet metal 42 of the base plate 4. The turbulator 6 comprises a surface-enlarging, flow-guiding, and heat-transferring structure, in particular in a turbulence portion 61 of the turbulator 6. The turbulator 6 is made of a metal with advantageous thermal conductivity, e.g. aluminum. The turbulator 6 can, e.g., also comprise a coating. The turbulator 6 can, e.g., be designed as a structured metal sheet. In order to achieve the greatest possible cooling efficiency, as much of the cross-sectional flow of the cooling channel 5 between the bottom plate 4 and the top plate 3 as possible is filled by the turbulator 6. For example, the turbulator 6 extends substantially planar parallel to the top plate 3 and/or to the, for example, planarly formed portion of sheet metal 43 of the bottom plate 4. The turbulence portion 61 of the turbulator 6, for example, has essentially the same surface area as the contact surface of the top plate 3 on which the electrical and/or electronic assembly 2 is arranged.

The turbulator 6 comprises a turbulence portion 61 and at least one blocking region 62. The turbulator 6 is designed to be integral, whereby the turbulence portion 61 and the blocking region 62 designate regions of the integrally designed turbulator 6. The turbulator 6 comprising the turbulence portion 61 and the blocking region 62 are made of a metal sheet.

The turbulence portion 61 of the turbulator 6 is provided for generating turbulent flow in the cooling fluid. The turbulence portion 61 is structured for generating turbulent flow in the cooling fluid. For example, a plurality of turbulence sections are formed on the turbulator 6, in the turbulence portion 61 of the turbulator 6, which are arranged at an angle to the direction of flow, in particular the longitudinal direction 11, of the cooling fluid through the cooling channel 5. The turbulence sections are used to add turbulence to the cooling fluid flowing through the cooling channel 5. As a result, the heat is able to be dissipated particularly effectively. For example, the turbulence sections can be wave-like or jagged, or can be formed as periodically recurring ridges and/or depressions in the turbulator. For example, the turbulence sections in the turbulence portions 61 of the turbulator 6 can be formed by cutting and forming, for example punching and bending, of the sheet metal from which the turbulator 6 is made.

To achieve a high level of cooling efficiency, as much of the cross-sectional flow of the cooling channel 5 as possible is covered by the turbulator 6. Given that the bottom plate 4 is a deep-drawn component, a demolding slope and radii on the edge of the depression 40 are required for the demolding process during deep drawing. The turbulence portion 61 of the turbulator 6 is arranged below the electrical and/or electronic assembly 2. On the edge of the cooling channel 5, bypass regions 55 are provided laterally adjacent to the turbulence portion 61 of turbulator 6, between the turbulence portion 61 of the turbulator 6, the bottom plate 4, and the top plate 3. The bypass regions 55 are situated adjacent to the electrical and/or electronic assembly 2 when viewed in the plane of the contact surface for the electrical and/or electronic assembly 2. The cooling channel 5 is designed to taper in the bypass region 55. No cooling flow turbulence takes place in the bypass regions 55.

In order minimize flow through the bypass regions 55 and thus to achieve a maximal cooling effect by the cooling device 1, blocking regions 62 are formed on the turbulator 6. The blocking regions 62 are arranged on the edge of the turbulator 6 adjacent to the turbulence portion 61 in the bypass region 55. The blocking regions 62 are arranged adjacent to the turbulence portion 61 of the turbulator 6 with respect to the longitudinal direction 11 of the cooling channel 5. The blocking regions 62 extend from the turbulence portion 61 into the bypass region 55. The blocking regions 62 extend from the turbulence portion 61 outwards to the contact region 8, in which the top plate 4 and the bottom plate 3 are contacted.

The blocking regions 62 have a geometry that is adapted to a deformation geometry of the deep-drawn bottom plate 4. The blocking regions 62 have a shape adapted to the deformation geometry of the bottom plate 4 such that the blocking regions 62 can block as much of a cross-sectional flow as possible in the bypass region 55. The bypass region 55 is therefore substantially completely blocked by the blocking regions 62. As a result, the cooling fluid flow must substantially pass entirely through the turbulence portion 61 of the turbulator 6 when flowing through the cooling channel 5. As a result, a particularly effective exploitation of the cooling potential of the cooling fluid flow is achieved, and the electrical and/or electronic assembly 2 can be optimally cooled.

The blocking regions 62 extend flat and perpendicular to the top plate 3 which is, e.g., designed to be level. The blocking regions 62 extend flat and perpendicular to the portion of metal sheet 42 which is, e.g., designed to be level.

The blocking regions 62 therefore face flat against the flow of the cooling fluid in the cooling channel 5. The blocking regions 62 extend flat, e.g., perpendicular to the longitudinal direction 11. As a result, the cross section of the bypass region 55 available for flow is significantly reduced or completely filled.

The blocking regions 62 are formed from the same metal sheet as the turbulence portion 61. The metal sheet is bent out of a plane parallel to the top plate 3 and/or the planar portion of metal sheet 42 for the blocking regions 62 such that it extends flat in the blocking regions 62, e.g. perpendicular or sloping with respect to the plane. Furthermore, the metal sheet can be stamped at the blocking regions 62 such that it is adapted to the geometry of the bottom plate 4, which extends to the top plate 3 in the bypass region 55. The metal sheet can be stamped such that it can adjoin and/or be connected to the top plate 3 and the bottom plate 4 in the bypass region 55. This is shown in FIGS. 2 and 3.

Further exemplary embodiments and mixed forms of the illustrated exemplary embodiments are clearly also possible.

1. A cooling device for cooling an electrical and/or electronic assembly (2), said cooling device comprising a top plate (3) and a bottom plate (4), wherein the bottom plate (4) is a deep-drawn component having a depression (40), wherein the top plate (3) and the bottom plate (4) are arranged such that, due to the depression (40), a cooling channel (5) is formed between the top plate (3) and the bottom plate (4), wherein the top plate (3) and the bottom plate (4) are connected to one another at a contact region (8) outside the depression (40), wherein it is possible for a cooling fluid flow of a cooling fluid to flow through the cooling channel (5) along a longitudinal direction (11), wherein the cooling device (1) further comprises at least one turbulator (6) arranged inside a turbulator section (56) of the cooling channel (5),
wherein a turbulence portion (61) for generating local turbulence in the flow of the cooling fluid and a blocking region (62) for locally blocking the flow of the cooling fluid are formed on the turbulator (6).

2. The cooling device according to claim 1, wherein the blocking region (62) projects from an edge (65) of the turbulence portion (61) into a bypass region (55) of the cooling channel (5) between the bottom plate (4) and the top plate (3).

3. The cooling device according to claim 1, wherein the blocking region (62) of the turbulator (6) extends from the turbulence portion (61) of the turbulator (6) towards the contact region (8) between the top plate (3) and the bottom plate (4).

4. The cooling device according to claim 1, wherein the turbulator (6) is formed from a curved metal sheet, wherein the metal sheet is bent such that the blocking region (62) is oriented flat against the longitudinal direction (11).

5. The cooling device according to claim 1, wherein the blocking region (62) of the turbulator (6) extends at least partially flat in a plane perpendicular to the longitudinal direction (11).

6. The cooling device according to claim 1, wherein the blocking region (62) of the turbulator (6) has a shape adapted to a geometry of the bottom plate (4).

7. The cooling device according to claim 1, wherein the blocking region (62) extends flat from the turbulence portion (61) towards the contact region (8) between the top plate (3) and the bottom plate (4).

8. The cooling device according to claim 1, wherein a plurality of blocking regions (62) are formed on the turbulator (6).

9. The cooling device according to claim 8, wherein the plurality of blocking regions (62) are formed at opposite edges (65) of the turbulence portion (61).

10. An electronic arrangement comprising:
a cooling device (1) according to claim 1, and
at least one electrical and/or electronic assembly (2) to be cooled, wherein the electrical and/or electronic assembly (2) is arranged on the top plate (3) or on the bottom plate (4).

11. The cooling device according to claim 6, wherein the blocking region (62) of the turbulator (6) has a shape adapted to a geometry of the bottom plate (4) on an edge of the depression (40).

12. The cooling device according to claim 8, wherein the plurality of blocking regions (62) are similarly configured.
